(19) United States
(12) Patent Application Publication
(10) Pub. No.: US 2011/0002187 A1
(43) Pub. Date: Jan. 6, 2011

(54) LATCH TYPE FUSE CIRCUIT AND OPERATING METHOD THEREOF

(76) Inventor: Wei-Ming Ku, Taipei County (TW)

Correspondence Address: NORTH AMERICA INTELLECTUAL PROPERTY CORPORATION, P.O. BOX 506, MERRIFIELD, VA, 22116, US

(21) Appl. No.: 12/496,643

(22) Filed: Jul. 2, 2009

(51) Int. Cl. G11C 17/18; G11C 7/10

(52) U.S. Cl. 365/225.7; 365/189.05

(57) ABSTRACT

A latch type fuse circuit includes a non-volatile memory, a PMOS transistor, and an output circuit. The non-volatile memory cell stores a logic bit. A voltage level of a source of the PMOS transistor determines the latch type fuse operating in the data program status or the data read status. In the data program status, a gate of the PMOS transistor receives a first signal including an address and the logic bit for determining the logic bit written in the non-volatile memory cell. The output circuit includes two NMOS transistors and an inverter. In the data read status, the output circuit can latch the logic bit.

### BACKGROUND OF THE INVENTION

1. Field of the Invention

The present invention relates to a latch type fuse circuit, and more particularly, to a latch type fuse using a signal including addresses and data information to operate.

2. Description of the Prior Art

Please refer to FIG. 1, which is a schematic diagram of a latch type fuse circuit 10 according to the prior art. The latch type fuse circuit 10 includes a non-volatile memory cell 12, three NMOS transistors N1, N2, N3, a PMOS transistor P1 and an inverter 14. The operation of the latch type fuse circuit 10 is controlled according to voltage levels of a port VCP, a port PGM, a port DIN, a port ZEN, and a port ZENSA.

Please refer to both FIG. 1 and FIG. 2. FIG. 2 is a list of voltage levels of the ports shown in FIG. 1. In the data program status, the voltage level of the port VCP is Vpp, which is higher than a voltage level Vdd. The port ZEN is applied with a high voltage (H) to turn on the NMOS transistor N2. The port PGM is applied to the high voltage (H) to turn on the NMOS transistor N3. The port ZENSA is applied to the voltage level Vpp to turn off the PMOS transistor P1. When the logic bit to be written is 1, the port DIN is applied to the high voltage (H). Therefore, the voltage level of the node DLU will be the high voltage (H) so that there will be no electrons carried into a floating gate FG of the non-volatile memory cell 12. When the logic bit to be written is 0, the port DIN is applied to a low voltage (L). The voltage level of the node DLU will be the low voltage (L), and there will be lots of electrons carried into the floating gate FG of the non-volatile memory cell 12.

In the data read status, the logic bit previously stored in the non-volatile memory cell 12 will be read out. According to FIG. 2, in the data read status, the voltage source VCP is set as Vdd. The port PGM is applied to the low voltage (L) to turn off the NMOS transistor N3 so that the voltage level of the node DLU can be maintained around an ideal value for fear of any read disturbance when the non-volatile memory cell 12 is in the data read status. The port ZENSA is applied to the low voltage (L) to turn on the PMOS transistor P1. The port ZEN is initially set to the high voltage (H). After a period of proper delay time, the port ZEN is then applied to the low voltage (L). When the logic bit stored in the non-volatile memory cell 12 is 0, the voltage level of the node DL will be charged to high, and then the voltage level of the output port DOUT will be low. Afterward, the NMOS transistor N1 turns off. Therefore, the voltage level of the node DL will be latched in the high voltage (H), and the voltage level of the output port DOUT will be latched in the low voltage (L). When the logic bit stored in the non-volatile memory cell 12 is 1, the voltage level of the node DL is set as the low voltage (L), the voltage level of the output port DOUT is the high voltage (H). The NMOS transistor N1 is conducted. Therefore, the voltage level of the node DL will be latched in the low voltage (L), and voltage level of the output port DOUT will be latched in the high voltage (H). Afterward, the port ZENSA will be applied to the high voltage (H) to turn off the PMOS transistor P1.

However, in the latch type fuse circuit according to the prior art, the NMOS transistor N3 is a high voltage tolerance device that needs a large dimension for a large program current. In addition, the PMOS transistor is a high voltage tolerance device to prevent the NMOS transistor s N1, N2 and the inverter 14 from breakdowns because a high voltage is applied when the cell is written in the program mode. The current of the non-volatile memory cell will be clamped at low voltage in the data read status, because the PMOS transistor P1 has a high-threshold voltage. Thus, the latch type fuse circuit according to the prior art cannot be used in the low operating voltage of advanced process.

### SUMMARY OF THE INVENTION

According to an embodiment of the present invention, a latch type fuse circuit comprises a non-volatile memory, a PMOS transistor, and an output circuit. The non-volatile memory cell stores a logic bit. The PMOS transistor has a source being coupled to a high voltage terminal, a gate for receiving a first signal including an address and the logic bit, and a drain being coupled to a first end of the non-volatile memory. The output circuit is coupled to a second end of the non-volatile memory.

According to another embodiment of the present invention, a method for operating a latch type fuse circuit is provided. The latch type fuse circuit comprises a non-volatile memory cell, a PMOS transistor, and an output circuit. The method comprises: controlling a voltage level of a source of the PMOS transistor to determine the latch type fuse operating in a data program status or a data read status; controlling a voltage level of a gate of the PMOS transistor to program the non-volatile memory cell in the data program status according to a signal including an address and a datum; and utilizing the output circuit to latch the datum in the data read status.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a latch type fuse circuit according to the prior art.

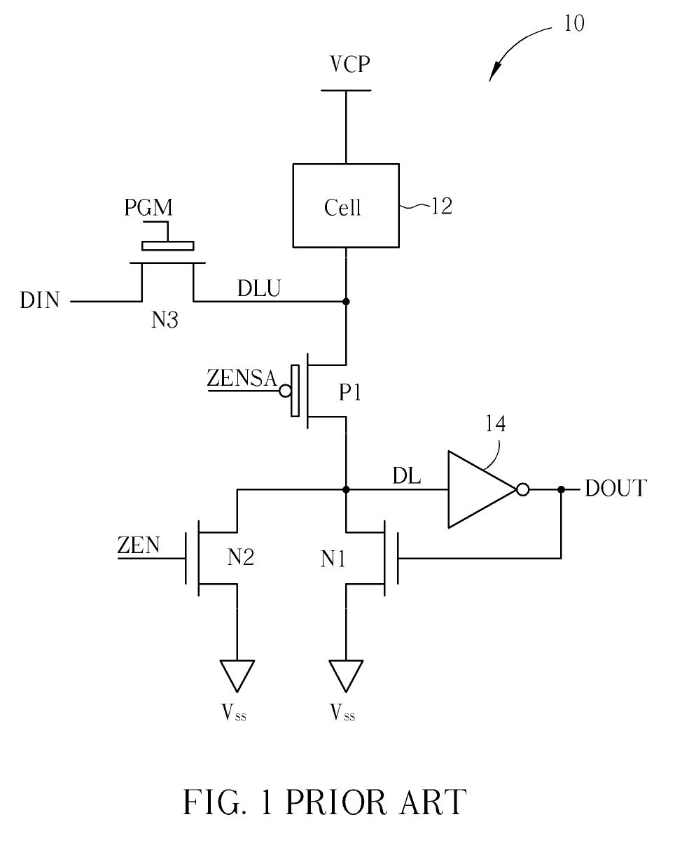

FIG. 2 is a list of voltage levels of the ports shown in FIG. 1.

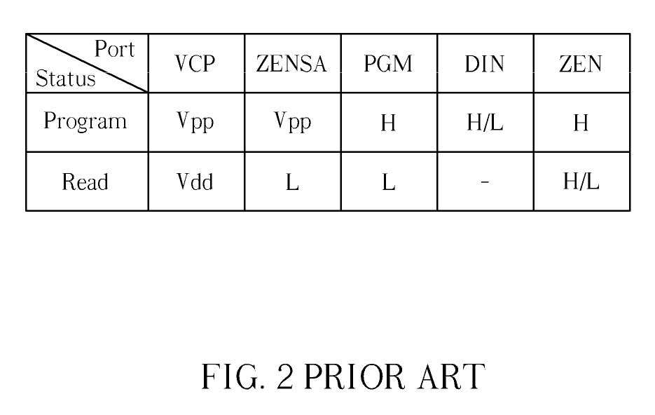

FIG. 3 is a schematic diagram of a latch type fuse circuit according to the present invention.

FIG. 4 is a list of voltage levels of the ports shown in FIG. 3.

FIG. 5 is a schematic diagram of a latch type fuse array according to the present invention.

FIG. 6 is a list of voltage levels of the ports shown in FIG. 5.

### DETAILED DESCRIPTION

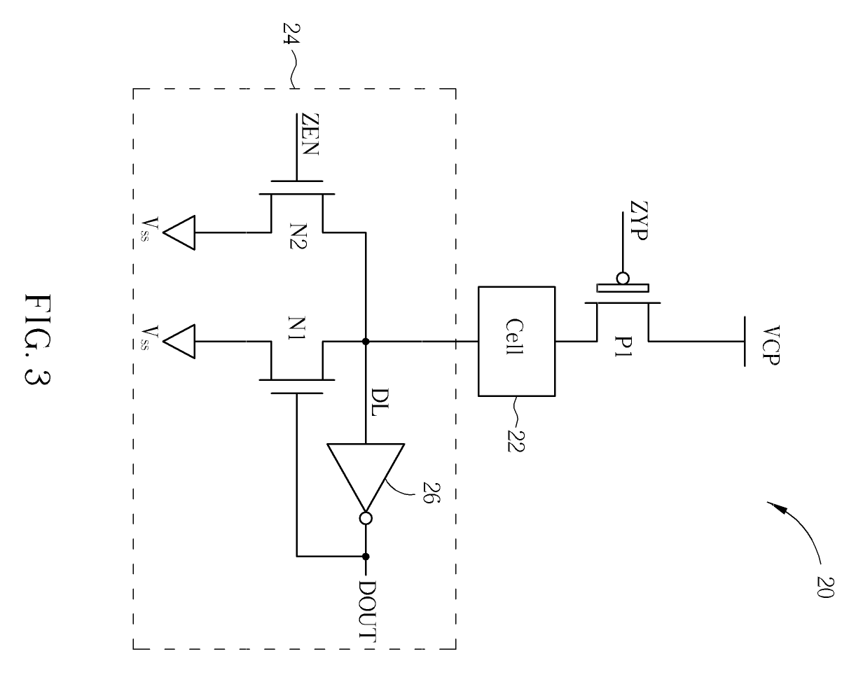

Please refer to FIG. 3, which is a schematic diagram of a latch type fuse circuit 20 according to the present invention. The latch type fuse is fabricated via a single-poly CMOS manufacturing process with an advantage of low cost for replacing the laser cutting technology. The latch type fuse circuit 20 includes a PMOS transistor P1, a non-volatile memory cell 22, and an output circuit 24. The non-volatile memory cell 22 is used to store a logic bit. A source of the PMOS transistor P1 is a port VCP. A gate of the PMOS transistor P1 is a port ZYP. A drain of the PMOS transistor P1 is coupled to a first end of the non-volatile memory 22. The output circuit 24 includes two NMOS transistors N1 and N2, and an inverter 26. The NMOS transistor Ni is coupled between a second end of the non-volatile memory 22 and a low voltage terminal Vss. The inverter 26 is coupled between the second end of the non-volatile memory cell 22 and a gate of the NMOS transistor Ni. The NMOS transistor N2 is coupled between the second end of the non-volatile memory cell and the low voltage terminal Vss. A gate of the NMOS transistor N2 is a port ZEN. The operation of the latch type fuse circuit 20 is controlled according to voltage levels of the port VCP, the port ZYP, and the port ZEN. The port ZYP receives a signal including addresses and data information.

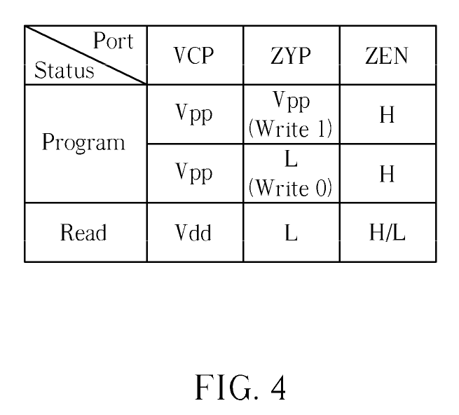

Please refer to both FIG. 3 and FIG. 4. FIG. 4 is a list of voltage levels of the ports shown in FIG. 3. In the data program status, the voltage level of the port VCP is Vpp, which is higher than a voltage level Vdd. The port ZEN is applied with a high voltage (H) to turn on the NMOS transistor N2. The NMOS transistor N2 will reset the node DL to a low voltage (L). When the logic bit to be written is 1, the port ZYP is applied to the voltage level Vpp to turn off the PMOS transistor P1. Therefore, no programming current flows from the PMOS transistor P1 to the non-volatile memory cell 22 so that there will be no electrons carried into a floating gate FG of the non-volatile memory cell 22. When the logic bit to be written is 0, the port ZYP is applied to the low voltage (L) to turn on the PMOS transistor P1. Therefore, there will be lots of electrons carried into the floating gate FG of the non-volatile memory cell 22. In comparison with the prior art, when the logic bit to be written is 1 or 0, the NMOS transistor N2 is turned on to reset the node DL to the low voltage (L).Thus, the low voltage tolerance devices including the NMOS transistor s N1, N2 and the inverter 26 do not need the high voltage tolerance device to isolate the high voltage.

In the data read status, the logic bit previously stored in the non-volatile memory cell 22 will be read out. According to FIG. 4, in the data read status, the voltage source VCP is set as Vdd. The port ZYP is applied to the low voltage (L) to turn on the PMOS transistor P1. The port ZEN is initially set to the high voltage (H). After a period of proper delay time, the port ZEN is then applied to the low voltage (L). When the logic bit stored in the non-volatile memory cell 12 is 0 the voltage level of the node DL will be changed to high, and then the voltage level of the output port DOUT will be low. Afterward, the NMOS transistor Ni turns off. Therefore, the voltage level of the node DL will be latched in the high voltage (H), and the voltage level of the output port DOUT will be latched in the low voltage (L). When the logic bit stored in the non-volatile memory cell 12 is 1, no cell current will charge the node DL. The voltage level of the node DL is set as the low voltage (L), and the voltage level of the output port DOUT is the high voltage (H). The NMOS transistor Ni is conducted. Therefore, the voltage level of the node DL will be latched in the low voltage (L), and voltage level of the output port DOUT will be latched in the high voltage (H).

The latch type fuse circuit 20 of the present invention utilizes the PMOS transistor P1 to program non-volatile memory cell, so no high voltage tolerance device is needed to isolate the high voltage for the output circuit 24, which will clamp the current of the non-volatile memory cell. The voltage level of the source of the PMOS transistor P1 is controlled to determine the latch type fuse operating in the data program status or the data read status. In the data program status, the voltage level of the gate of the PMOS transistor P1 is controlled to determine the logic bit written in the non-volatile memory cell. Thus, the latch type fuse circuit of the present invention can be used in the low operating voltage of advanced process. It should be noted that the gate of the PMOS transistor P1 receives the signal including addresses and data information. The signal including the addresses and the data information can be generated by a decoder. The output circuit can latch the logic bit in the data read status. According to the present invention, the latch type fuse circuit has no high voltage tolerance device to isolate the high voltage for the output circuit 24, so the latch type fuse circuit needs only a small dimension for a large program current. In addition, the current of the non-volatile memory cell will not be clamped at low voltage in the data read status. Thus, the latch type fuse circuit of the present invention can be used in the low operating voltage of advanced process.

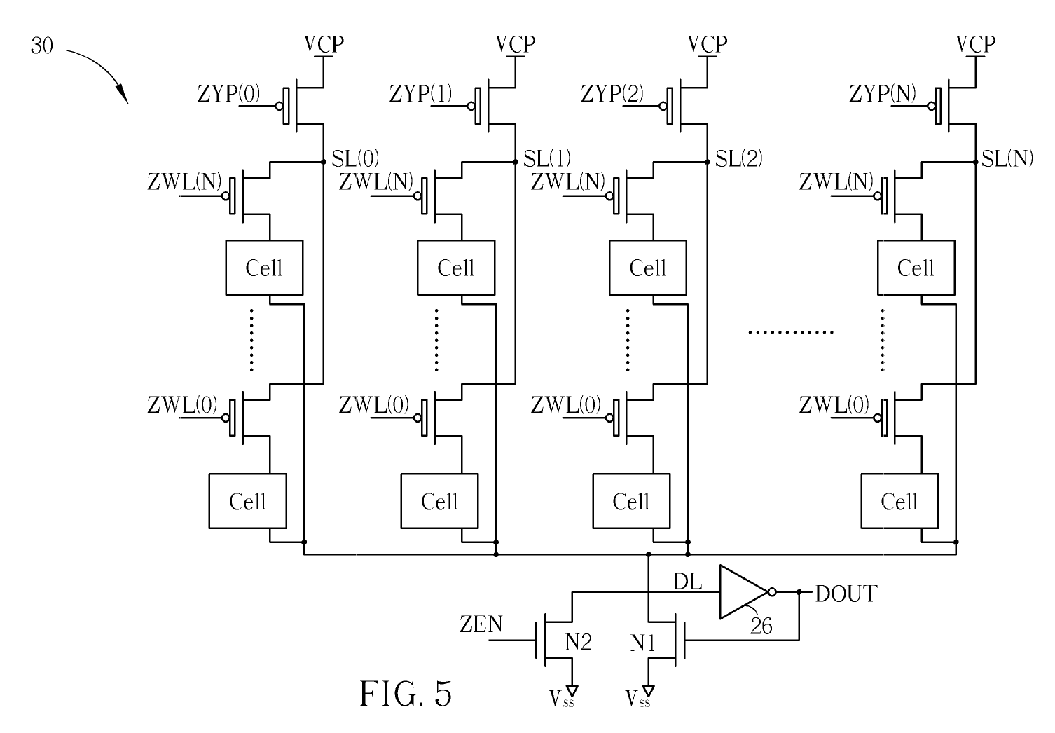

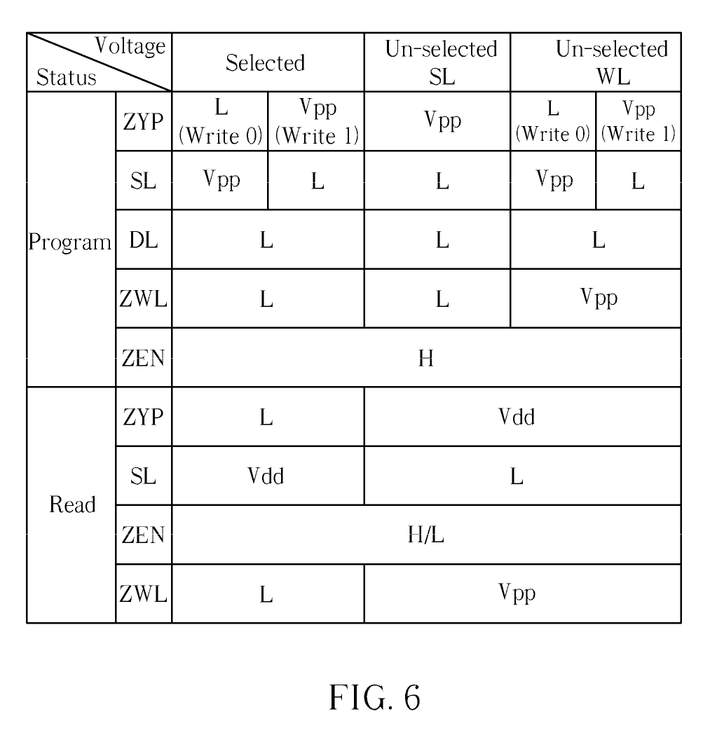

Please refer to FIG. 5 and FIG. 6. FIG. 5 is a schematic diagram of a latch type fuse array 30 according to the present invention. FIG. 6 is a list of voltage levels of the ports shown in FIG. 5. The port ZYP(0) to the port ZYP(N) are used to input signals to source lines. The port ZWP(0) to the port ZWP(N) are used to input signals to word lines. The ports ZYP receive signals including addresses and data information. For example, in the data program status, when the logic bit to be written is 0, for the selected memory cell, the ports ZYP, ZWL, and ZEN are applied to the voltages L, L, and H respectively; for the un-selected memory cell, the ports ZYP and ZWL are applied to the voltages Vpp and Vpp respectively. The node SL of the selected memory is applied to the voltage Vpp and the node DL is set to the low voltage (L), so there will be lots of electrons carried into the floating gate FG of the selected memory cell. The node SL of the un-selected memory is applied to the low voltage (L) and the node DL is set to the low voltage (L), so there will be no electrons carried into the floating gate FG of the un-selected memory cell.

In conclusion, the latch type fuse circuit of the present invention includes a non-volatile memory, a PMOS transistor, and an output circuit. The non-volatile memory cell stores a logic bit. A voltage level of a source of the PMOS transistor determines the latch type fuse operating in the data program status or the data read status. In the data program status, a gate of the PMOS transistor receives a first signal including an address and the logic bit for determining the logic bit written in the non-volatile memory cell. The output circuit includes two NMOS transistors and an inverter. In the data read status, the output circuit can latch the logic bit.

Those skilled in the art will readily observe that numerous modifications and alterations of the device and method may be made while retaining the teachings of the invention.

What is claimed is:

1. A latch type fuse circuit, comprising:
a non-volatile memory cell for storing a logic bit;
a PMOS transistor having a source being coupled to a high voltage terminal, a gate for receiving a first signal including an address and the logic bit, and a drain being coupled to a first end of the non-volatile memory; and
an output circuit being coupled to a second end of the non-volatile memory.

2. The latch type fuse circuit of claim 1, wherein the output circuit comprises:
a first NMOS transistor being coupled between the second end of the non-volatile memory and a low voltage terminal;
an inverter being coupled between the second end of the non-volatile memory cell and a gate of the first NMOS transistor; and
a second NMOS transistor being coupled between the second end of the non-volatile memory cell and the low voltage terminal, a gate of the second NMOS transistor for receiving a second signal.

3. The latch type fuse circuit of claim 2, wherein when the latch type fuse circuit is in a data program status, the second signal is set to a voltage level of a high voltage.

4. The latch type fuse circuit of claim 2, wherein when the latch type fuse circuit is in a data read status, the second signal is set to a voltage level of a high voltage and then a voltage level of a low voltage after a period of delay time.

5. The latch type fuse circuit of claim 1, wherein when the latch type fuse circuit is in a data program status and the logic bit is “1”, the source of the PMOS transistor is applied to a programming voltage and the first signal is set to a voltage level of the programming voltage.

6. The latch type fuse circuit of claim 1, wherein when the latch type fuse circuit in a data program status and the logic bit is “0”, the source of the PMOS transistor is applied to a programming voltage and the first signal is set as a voltage level of a low voltage.

7. The latch type fuse circuit of claim 1, wherein when the latch type fuse circuit in a data read status, the source of the PMOS transistor is applied to a high voltage and the first signal is set as a voltage level of a low voltage.

8. The latch type fuse circuit of claim 1, wherein the non-volatile memory cell is a floating-gate PMOS memory cell.

9. A method for operating a latch type fuse circuit, the latch type fuse circuit comprising a non-volatile memory cell, a PMOS transistor, and an output circuit, the method comprising:
controlling a voltage level of a source of the PMOS transistor to determine the latch type fuse operating in a data program status or a data read status;
controlling a voltage level of a gate of the PMOS transistor to program the non-volatile memory cell in the data program status according to a signal including an address and a datum; and
utilizing the output circuit to latch the datum in the data read status.

10. The method of claim 9, further comprising:
utilizing a decoder to generating the signal including the address and the datum.

11. The method of claim 9, wherein the output circuit comprises:
a first NMOS transistor being coupled between the non-volatile memory cell and a low voltage terminal;
a second NMOS transistor being coupled between the non-volatile memory cell and the low voltage terminal; and
an inverter being coupled between the non-volatile memory and a gate of the first NMOS transistor.
